(19) United States
(12) Patent Application Publication
(10) Pub. No.: US 2008/0075221 A1
(43) Pub. Date: Mar. 27, 2008

(54) APPARATUS AND RELATED METHOD FOR DETECTING PHASE OF INPUT DATA

(76) Inventor: Jia-Long Lai, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/533,777

(22) Filed: Sep. 21, 2006

(51) Int. Cl. H03D 3/24

(52) U.S. Cl. 375/376

(57) ABSTRACT

An apparatus for detecting a phase of an input signal includes: a phase detector unit for detecting the phase of the input signal referring to a plurality of clock signals having different phases and for outputting a plurality of phase detection results, wherein each of the phase detection results represents a candidate phase of the input signal and corresponds to one of the clock signals; and a phase decision unit, coupled to the phase detector unit, for determining the phase of the input signal according to the phase detection results.

### BACKGROUND

The present disclosure relates to an apparatus and a related method for detecting a phase of an input signal, and more particularly, to an apparatus and the related method applied in Delay-Locked Loop (DLL) circuits for detecting a phase of an input signal.

Many high speed serial links (e.g., USB 2.0 or HDMI) have become very popular interfaces for transferring data. In general, the conventional Delay-Locked Loop (DLL) circuit is utilized for extracting clock and data from the input serial data. In the design process of the DLL circuit, some number of delayed clock signals are utilized to sample the input data for detecting the phase of data. Further, the DLL circuit will select a specific signal with 180 degrees phase difference from the rising edge or the falling edge of the input data, and the DLL circuit will then lock the specific clock signal being the recovered clock signal to recover the data. For example, please refer to FIG. 1. FIG. 1 shows a schematic diagram illustrating the conventional DLL circuit selecting the recovered clock signal from a plurality of clock signals. As shown in FIG. 1, assume that a conventional DLL circuit generates six clock signals with different Phases 1 through 6. The Phases 1 through 6 are represented to the rising edge of the clock signals 1 through 6 respectively. According to the rising edge or falling edge of the input data, since the phase 5 of the clock signal 5 is shifted from an edge of the input signal by 180 degrees. Thus, the conventional DLL circuit will select the clock signal 5 to be the recovered clock signal and then recover the input data according to the recovered clock.

However, the phase of the input data may shift frequently because of what is referred to as a jitter disturbance. The conventional DLL circuit has great difficulty in locking the specific clock signal to be the recovered clock due to the phase shift of the input data. Moreover, the conventional DLL circuit may lock the wrong clock signal to recover the data. In this case, the input data recovered form the recovered clock may involve in the setup time or the hold time violation of the edge of the recovered data. Therefore, the conventional DLL circuit may recover the wrong data result. Additionally, the required time of locking the phase of the input data by the conventional DLL circuit is unpredictable; so much, so that it may increase the design difficulty and unstable situation in the conventional DLL circuit. Therefore, if is important to discover how to recover the clock and data reliably. This function is a critical part of the DLL circuit.

### SUMMARY

It is one of the objectives of the present disclosure to provide an apparatus and a related method applied in Delay-Locked Loop (DLL) circuit for detecting a phase of an input signal, to solve the above-mentioned problems.

According to an aspect of the present disclosure, an apparatus for detecting a phase of an input signal is disclosed. The apparatus includes a phase detector unit for detecting the phase of the input signal referring to a plurality of clock signals having different phases and for outputting a plurality of phase detection results, wherein each of the phase detection results represents a candidate phase of the input signal and corresponds to one of the clock signals; and a phase decision unit, coupled to the phase detector unit, for determining the phase of the input signal according to the phase detection results.

According to another aspect of the present disclosure, an apparatus for producing a recovery data signal from an input signal is disclosed. The apparatus includes: a phase detector unit for detecting the phase of the input signal referring to a plurality of clock signals having different phases and for outputting a plurality of phase detection results, wherein each of the phase detection results represents a candidate phase of the input signal and corresponds to one of the clock signals; a phase decision unit, coupled to the phase detector unit, for determining the phase of the input signal according to the phase detection results; and a clock/data recovery unit, coupled to the phase decision unit, for determining a recovery clock signal according to the phase of the input signal determined by the phase decision unit and the clock signals generated from the multi-phase clock generating unit, and for producing the recovery data signal by sampling the input signal according to the recovery clock signal.

According to another aspect of the present disclosure, a method for detecting a phase of an input signal is disclosed. The method includes detecting a candidate phase of the input signal referring to a plurality of clock signals having different phases and generating a plurality of phase detection results, wherein each of the phase detection results represents the candidate phase of the input signal and corresponds to one of the clock signals; and then determining the phase of the input signal according to the phase detection results.

According to another aspect of the present disclosure, a method for detecting a phase of an input signal is disclosed. The method includes: detecting a candidate phase of the input signal referring to a plurality of clock signals having different phases and generating a plurality of phase detection results, wherein each of the phase detection results represents the candidate phase of the input signal and corresponds to one of the clock signals; determining the phase of the input signal according to the phase detection results; and determining a recovery clock signal according to the phase of the input signal and the clock signals, and producing a recovery data signal by sampling the input signal according to the recovery clock signal.

The DLL circuit of the present disclosure utilizes the phase average mechanism to search for and more precisely recover the clock signal to detect the phase of an input data signal. The phase decision unit provide by the DLL circuit of the present invention can gather the phases of clocks signals which are possible candidates to be the recover signal and determine the recover clock signal according to the average mechanism. Therefore, the jitter tolerance of the DLL circuit of the present disclosure is significantly improved, and the timing margin of the DLL circuit is also wide enough to be utilized in low end or low power arrangements.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic diagram illustrating the conventional DLL circuit selecting the recovered clock signal form a plurality of clock signals.

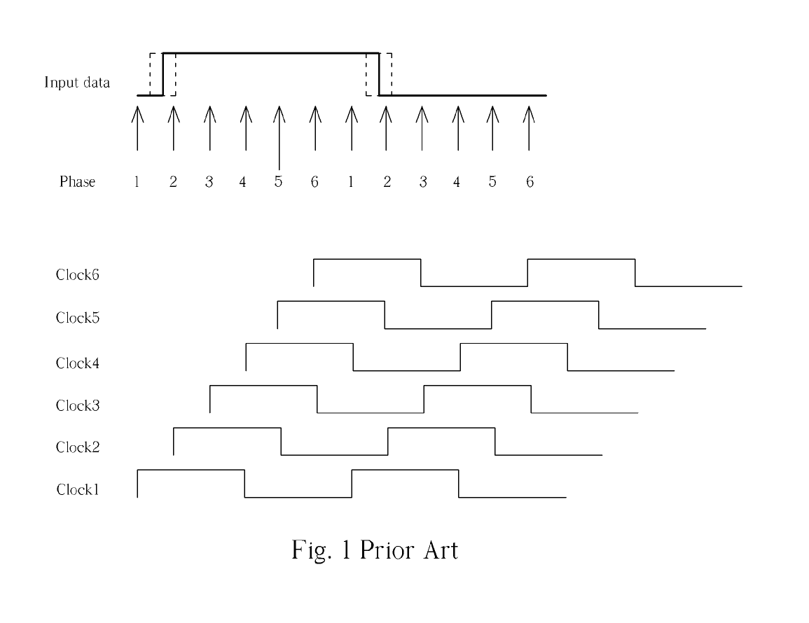

FIG. 2 shows a schematic diagram illustrating the distribution of the phase of the input data.

FIG. 3 shows a first schematic diagram of the phase average concept in the present disclosure.

FIG. 4 shows a second schematic diagram of the phase average concept in the present disclosure.

FIG. 5 shows a block diagram of a Delay-Locked Loop (DLL) circuit according to a first embodiment of the present disclosure.

FIG. 6 shows a schematic diagram of a look-up table utilized by the decision logic.

FIG. 7 shows a flowchart illustrating the detailed operation of phase average mechanism performed by the DLL circuit shown in FIG. 5.

FIG. 8 shows a block diagram of a Delay-Locked Loop (DLL) circuit according to a second embodiment of the present disclosure.

### DETAILED DESCRIPTION

Certain terms are used throughout the following description and claims to refer to particular system components. As one skilled in the art will appreciate, consumer electronic equipment manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” The terms “couple” and “couples” are intended to mean either an indirect or a direct electrical connection. Thus, if a first device couples to a second device, that connection may be through a direct electrical connection, or through an indirect electrical connection via other devices and connections.

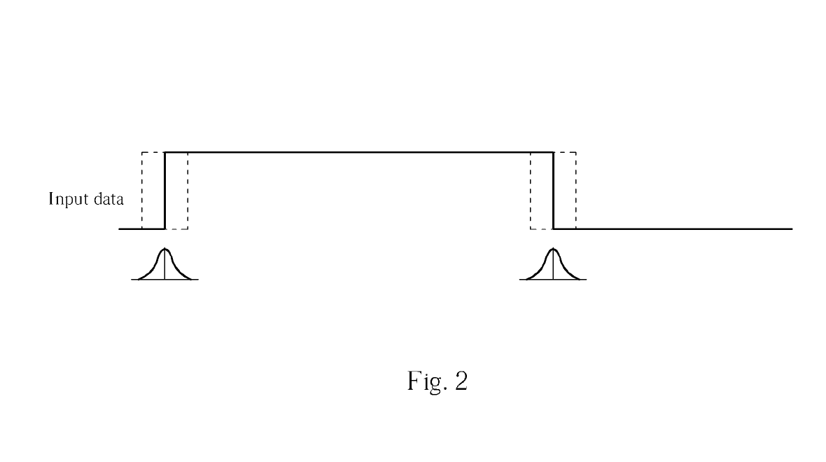

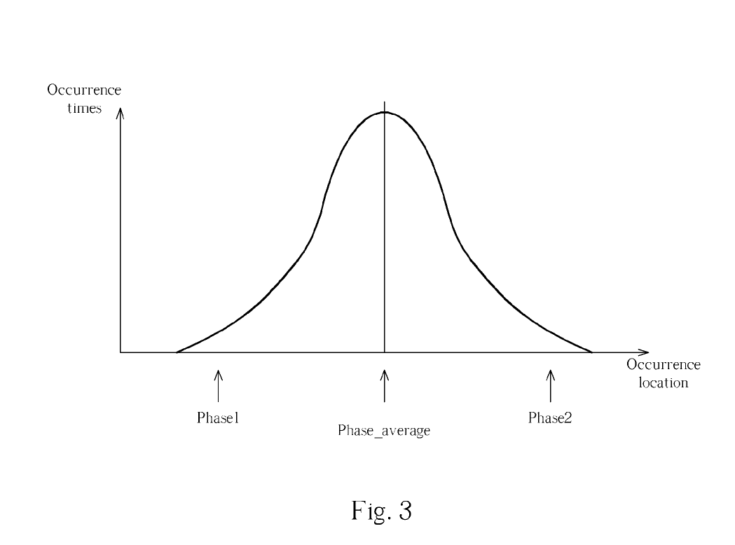

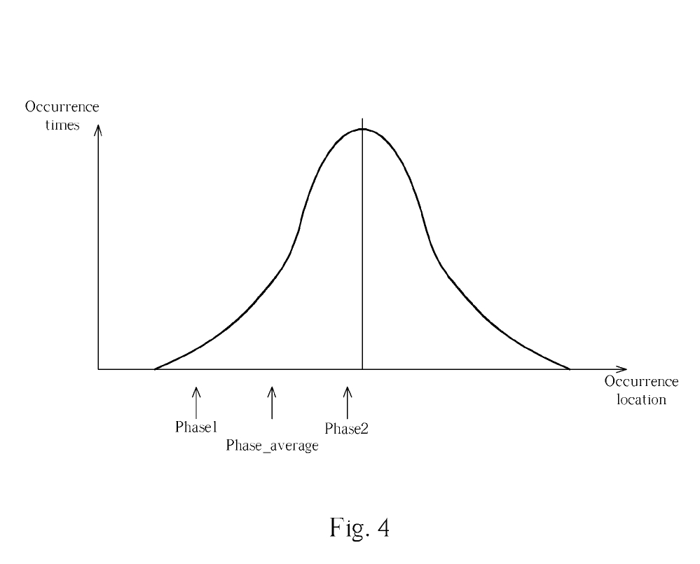

Please refer to FIG. 2. FIG. 2 shows a schematic diagram illustrating the distribution of the phase of the input data. As mentioned above, the phase of the input data may shift frequently because of the jitter disturbance. So, it is extremely difficult to determine whether the detected phase of the clock signal is exactly the real phase corresponding to the input data or otherwise. As shown in FIG. 2, the relationship between the occurrence location and the occurrence times of the edge of the input data is in a normal distribution. Therefore, the present disclosure provides a phase average concept to determine the real phase of the clock signal. Please refer to FIG. 3. FIG. 3 shows a first schematic diagram of the phase average concept in the present disclosure. As shown in FIG. 3, assuming that Phase 1 is the occurrence location of one detected phase and that the Phase 2 is the occurrence location of another detected phase. Since Phase 1 and Phase 2 are located at the two sides of the real phase (i.e., the middle point), therefore, the average position (i.e., the Phase_average shown in FIG. 3) of the Phase 1 and the Phase 2 will be closer to the real phase than the Phase 1 and the Phase 2. Additionally, please refer to FIG. 4. FIG. 4 shows a second schematic diagram of the phase average concept in the present disclosure. In this case, Phase 1 and Phase 2 are both located on one side of the real phase (i.e., the middle point). Although the average position (i.e., the Phase_average shown in FIG. 4) of the Phase 1 and the Phase 2 are not closer to the real phase than Phase 2, it is a better situation than Phase 1 so that it can avoid the system selecting the worst situation. Since the jitter of each detected phase is unknown, and there is no way to detect the jitter of each detected phase, therefore, the averaged phase is the better choice as compared to the option of selecting between Phase 1 and Phase 2.

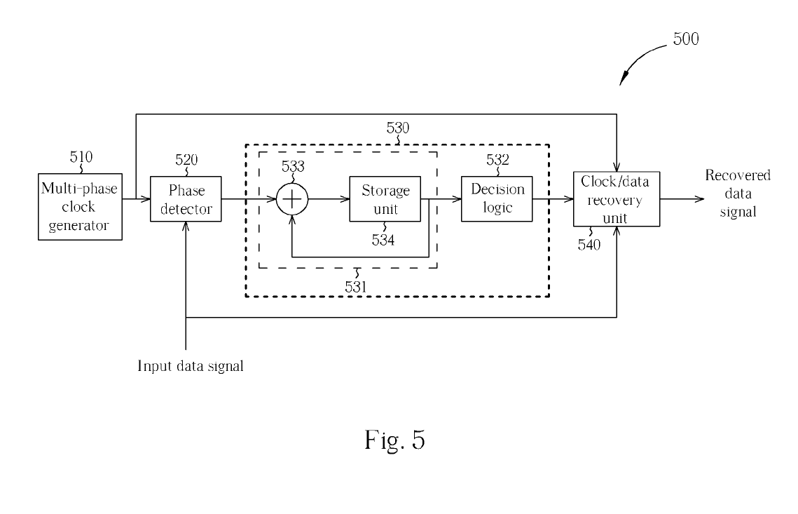

Please refer to FIG. 5. FIG. 5 shows a block diagram of a Delay-Locked Loop (DLL) circuit 500 according to a first embodiment of the present disclosure. The DLL circuit 500 includes a multi-phase clock generator 510, a phase detector 520, a phase decision unit 530, and a clock/data recovery unit 540. The phase decision unit 530 includes a combining unit 531 and a decision logic 532. And the combining unit 531 includes an OR logic gate 533 and a storage unit 534. The multi-phase clock generator 510 is utilized for generating the clock signals having different phases, and the phases of the clock signals generated by the multi-phase clock generator 510 are evenly spaced within a bit period of the input signal. In practice, the multi-phase clock generator 510 can be embodied in a Phase-lock loop (PLL) circuit. In this embodiment, please assume that the multi-phase clock generator 510 generates six clock signals with difference phases.

Next, the phase detector 520 is utilized for detecting the phase of the input data signal referring to a plurality of clock signals having different phases and for outputting a plurality of phase detection results. Since the configuration and operation of the phase detector 520 is considered well known to those having average skill in the related art, a further detailed description is hereinafter omitted for the sake of brevity. Please note that, each of the phase detection results represents a candidate phase of the clock signal corresponding to the phase of the input data signal. That is, if the phase detector 520 detects that a phase of a specific clock signal of the clock signals is shifted from an edge of the input data signal by 180 degrees, the phase detector 520 outputs a phase detection result corresponding to the specific clock signal to indicate a candidate phase of the input data signal. In this preferred embodiment of the present disclosure, each of the phase detection results has a plurality of bits each representing one of the clock signals. For example, since there are six clocks signals with different phases generated by the multi-phase clock generator 510, the phase detection result thus has six bits number to indicate which clock signal may be represented to a candidate phase of the input data signal. If the phase detector 520 detects that a phase of a specific clock signal is a candidate phase of the input data signal, the phase detector 520 sets a first logic value (e.g., the digit value “1”) to a specific bit of a phase detection result corresponding to the specific clock signal and sets a second logic value (e.g., the digit value “0”) to the remaining bits. For example, if the phase detection result shows a six bits “010000”, that is, the second clock signal will be represented to a candidate phase of the input data signal. The same, if the phase detection result shows a six bits “000010”, that is, the fifth clock signal will be represented to a candidate phase of the input data signal.

After the phase detector 520 determines a phase detection result and send the phase detection result into the combining unit 531 of the phase decision unit 530. The OR logic gate 533 of the combining unit 531 will perform an OR logic operation on a phase detection result outputted from the phase detector 520 and the data currently stored in the storage unit 534 to generate a new combination result to be stored by the storage unit 534. That is, in this preferred embodiment of the present invention, if the first phase detection result showing a six bits “000010” is sent to the phase decision unit 530 and stored in the storage unit 534. Next, the second phase detection result with a six bits “000100” is generated by the phase detector 520 and is sent into the combining unit 531. The OR logic gate 533 will perform the OR logic operation to the first and the second phase detection results and generate a new combination result with a six bits “000110”. That is, the combination result stored in the storage unit 534 indicates all of the possible phases of the clock signals being the candidate phase of the input data signal. For example, the combination result with a six bits “000111” indicates that one of the four, the fifth, and the sixth phases of clock signals will be represented to the phase of the input data signal.

After a predetermined period of time allowing the combining unit 531 for gathering enough information, the combining unit 531 will send the current combination result to the decision logic 532. The decision logic 532 is utilized for determining the phase of the input signal according to the combination result. Please note that, there are a plurality of phase-average mechanisms for the decision logic 532 to determine the final phase of clock signal being represented to the phase of the input signal. For example, in one embodiment of the present disclosure, the decision logic 532 can determine the phase of the clock signal according to the number of the digit value 1 in the combination result. If the combination result has an odd number of successive bits having the logic value “1” and respectively corresponding to successive clock signals, the decision logic 532 utilizes a middle bit of the successive bits to determine the phase of the input data signal; and if the combination result has an even number of successive bits having the logic value “1” and respectively corresponding to successive clock signals, the decision logic 532 utilizes one of the middle two bits of the successive bits to determine the phase of the input data signal. That is, if the combination result is “001110”, the decision logic 532 will select the phase of the clock signal corresponding to the middle bits “1” (i.e., the fourth clock signal) to be the final decision. And if the combination result is “001100”, the decision logic 532 can select any one of the phases of the clock signals corresponding to the middle 2 bits (i.e., the third or the fourth clock signal) to be the final decision.

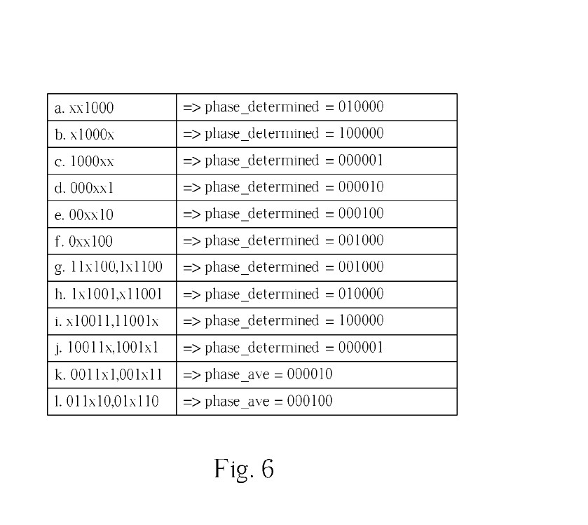

Please note that, in the present disclosure, the phase-average mechanism is not limited to the above definition. That is, in other embodiments of the present disclosure, the phase-average mechanism can be assigned by different conditions depending on the design requirements at hand. For example, in another embodiment of the present disclosure, a look-up table can be set in the decision logic 532 to provide assistance to the decision logic 532 in determining the final decision. Please refer to FIG. 6. FIG. 6 shows a schematic diagram of a look-up table utilized by the decision logic 532. As shown in FIG. 6, there are a multitude of situations regarding the combination result to assist in determining the phase of the input signal according to the combination result. Wherein the “X” signs shown in the FIG. 6 is referred to as a “don't care” situation. That is, in the situation “a”, no matter what the digit value of the first and the second phase of the clock signal are, for example, “1” or “0”, the final decision “010000” is represented to the second clock signal will be assigned to determine to phase of the input data signal. Further details and explanation of “don't care” regarding the “X” shown in FIG. 6 are well know to those of average skill in the related art and are therefore omitted hereinafter for the sake of brevity. Finally, the clock/data recovery unit 540 determines a recovery clock signal according to the final decision generated by the phase decision unit 530, and produces a recovery data signal by sampling the input signal according to the recovery clock signal.

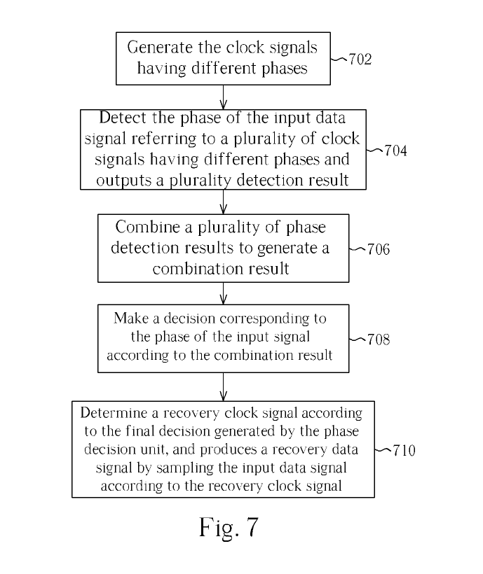

Please refer to FIG. 7. FIG. 7 shows a flowchart illustrating the detailed operation of the phase average mechanism performed by the DLL circuit 500 shown in FIG. 5. The steps of the flowchart need not be in the exact order shown in FIG. 7 if the result achieved is substantially the same. The flowchart contains the following steps:

Step 702: The multi-phase clock generator 510 generates the clock signals having different phases.

Step 704: The phase detector 520 detects the phase of the input data signal referring to a plurality of clock signals having different phases and outputs a plurality detection result.

Step 706: The combining unit 531 combines a plurality of phase detection results to generate a combination result.

Step 708: The decision logic 532 is utilized for making a decision corresponding to the phase of the input signal according to the combination result.

Step 710: The clock/data recovery unit 540 determines a recovery clock signal according to the final decision generated by the phase decision unit 530, and produces a recovery data signal by sampling the input data signal according to the recovery clock signal.

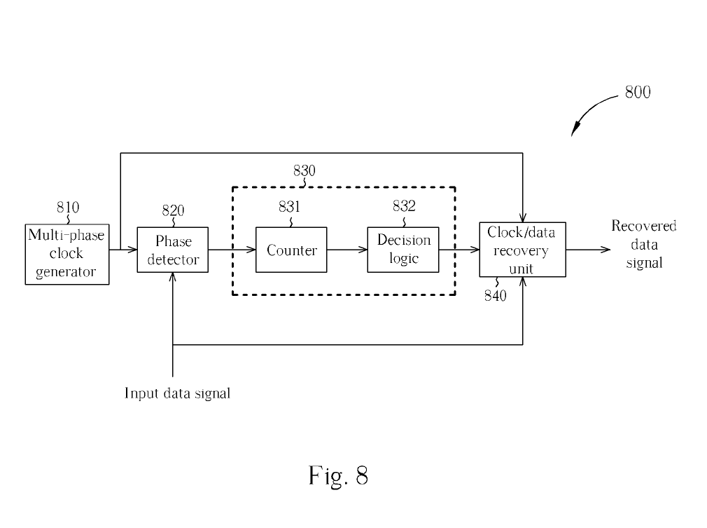

Please refer to FIG. 8. FIG. 8 shows a block diagram of a Delay-Locked Loop (DLL) circuit 800 according to a second embodiment of the present disclosure. The DLL circuit 800 includes a multi-phase clock generator 810, a phase detector 820, a phase decision unit 830, and a clock/data recovery unit 840. The phase decision unit 830 includes a counter 831 and a decision logic 832. Since the elements of the same name in the first and the second embodiments of the present disclosure have the same function and operation, their detailed descriptions are omitted herein for the sake of brevity. The primary difference between the DLL circuit 500 and the DLL circuit 800 is that after the phase detector 820 generates the detection result, the counter 831 of the phase decision unit 830 then counts the occurrence frequency of the first logic value in a specific bit of each phase detection result. That is, in a predetermined period of time, if the detection result with six bits “011100”, that is, the second, the third, and the fourth clock signals may be the final decision to determine the phase of the input data signal. Next, the counter 831 will count the appearance times for each of the candidate clock signals. And then the decision logic 832 will determine the most frequently occurring phase of the clock signal according to the counters and then send the final decision to the clock/data recovery unit 840.

In contrast to the related art DLL circuit, the DLL circuit of the present disclosure utilizes the phase average mechanism to search more precisely for the recover clock signal to detect the phase of an input data signal. The phase decision unit provide by the DLL circuit of the present disclosure can gather the phases of clock signals which are possible candidates to be the recover signals and then determine the recover clock signal according to the average mechanism. Therefore, the jitter tolerance of the DLL circuit of the present disclosure is significantly improved, and the timing margin of the DLL circuit is also sufficiently wide enough to be utilized in low end or low power situations.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An apparatus for detecting a phase of an input signal, comprising:
a phase detector unit for detecting the phase of the input signal referring to a plurality of clock signals having different phases and for outputting a plurality of phase detection results, wherein each of the phase detection results represents a candidate phase of the input signal and corresponds to one of the clock signals; and
a phase decision unit, coupled to the phase detector unit, for determining the phase of the input signal according to the phase detection results.

2. The apparatus of claim 1, further comprising:
a multi-phase clock generator, coupled to the phase detector unit for generating the clock signals having different phases;
wherein the phases of the clock signals are evenly spaced within a bit period of the input signal.

3. The apparatus of claim 1, wherein if the phase detector unit detects that a phase of a specific clock signal of the clock signals is shifted from an edge of the input signal by 180 degrees, the phase detector unit outputs a phase detection result corresponding to the specific clock signal to indicate a candidate phase of the input signal.

4. The apparatus of claim 1, wherein the phase decision unit comprises:
a combining unit, coupled to the phase detector unit, for combining the phase detection results to generate a combination result; and
a decision logic, coupled to the combining unit, for determining the phase of the input signal according to the combination result.

5. The apparatus of claim 4, wherein the combining unit comprises:
a storage unit, coupled to the decision logic, for storing the combination result; and
an OR logic gate, coupled between the phase detector unit and the storage unit, for performing an OR logic operation on a phase detection result outputted from the phase detector unit and data currently stored in the storage unit to generate new data to be stored by the storage unit.

6. The apparatus of claim 5, wherein each of the phase detection results has a plurality of bits each representing one of the clock signals; if the phase detector unit detects that a phase of a specific clock signal is a candidate phase of the input signal, the phase detector unit sets a first logic value to a specific bit of a phase detection result corresponding to the specific clock signal and sets a second logic value to the remaining bits; and the decision logic determines the phase of the input signal according to bits of the first logic value in the combination result.

7. The apparatus of claim 6, wherein if the combination result has an odd number of successive bits having the first logic value and respectively corresponding to successive clock signals, the decision logic utilizes a middle bit of the successive bits to determine the phase of the input signal; and if the combination result has an even number of successive bits having the first logic value and respectively corresponding to successive clock signals, the decision logic utilizes one of middle two bits of the successive bits to determine the phase of the input signal.

8. The apparatus of claim 6, wherein the decision logic comprises a look-up table, and utilizes the look-up table and bits of the first logic value in the combination result to determine the phase of the input signal.

9. The apparatus of claim 1, wherein the phase decision unit selects a most frequently occurring phase among the phases of the clock signals to determine the phase of the input signal.

10. The apparatus of claim 9, wherein each of the phase detection results has a plurality of bits each representing one of the clock signals; if the phase detector unit detects that a phase of a specific clock signal is a candidate phase of the input signal, the phase detector unit sets a first logic value to a specific bit of a phase detection result corresponding to the specific clock signal and sets a second logic value to the remaining bits; and the phase decision unit comprises:
a counters for counting occurrence of the first logic value in a specific bit of each phase detection result; and
a decision logic, coupled to the counters, for determining the most frequently occurring phase according to counter values of the counters.

11. The apparatus of claim 1, further comprising:
a clock/data recovery unit, coupled to the phase decision unit, for determining a recovery clock signal according to the phase of the input signal determined by the phase decision unit and the clock signals generated from the multi-phase clock generating unit, and for producing a recovery data signal by sampling the input signal according to the recovery clock signal.

12. An apparatus for producing a recovery data signal from an input signal, comprising:
a phase detector unit for detecting the phase of the input signal referring to a plurality of clock signals having different phases and for outputting a plurality of phase detection results, wherein each of the phase detection results represents a candidate phase of the input signal and corresponds to one of the clock signals;
a phase decision unit, coupled to the phase detector unit, for determining the phase of the input signal according to the phase detection results; and
a clock/data recovery unit, coupled to the phase decision unit, for determining a recovery clock signal according to the phase of the input signal determined by the phase decision unit and the clock signals generated from the multi-phase clock generating unit, and for producing the recovery data signal by sampling the input signal according to the recovery clock signal.

13. An method for detecting a phase of an input signal, comprising:
(a) detecting a candidate phase of the input signal referring to a plurality of clock signals having different phases and generating a plurality of phase detection results, wherein each of the phase detection results represents the candidate phase of the input signal and corresponds to one of the clock signals; and
(b) determining the phase of the input signal according to the phase detection results.

14. The method of claim 13, wherein the phases of the clock signals are evenly spaced within a bit period of the input signal.

15. The method of claim 13, wherein step (a) further comprises: if a phase of a specific clock signal of the clock signals is shifted from an edge of the input signal by 180 degrees, generating a phase detection result corresponding to the specific clock signal to indicate a candidate phase of the input signal.

16. The method of claim 13, wherein step (a) further comprises:
(a1) combining the phase detection results to generate a combination result; and
(a2) determining the phase of the input signal according to the combination result.

17. The method of claim 16, wherein step (a1) further comprises:
performing an OR logic operation on a phase detection result and the combination result to update the combination result.

18. The method of claim 17, wherein each of the phase detection results has a plurality of bits each representing one of the clock signals; step (a) further comprises: (a3) if a phase of a specific clock signal is detected to be a candidate phase of the input signal, setting a first logic value to a specific bit of a phase detection result corresponding to the specific clock signal and a second logic value is set to the remaining bits; and step (a2) further comprises: (a2-1) determining the phase of the input signal according to bits of the first logic value in the combination result.

19. The method of claim 18, wherein step (a2-1) further comprises:
if the combination result has an odd number of successive bits having the first logic value and respectively corresponding to successive clock signals, utilizing a middle bit of the successive bits to determine the phase of the input signal; and
if the combination result has an even number of successive bits having the first logic value and respectively corresponding to successive clock signals, utilizing one of middle two bits of the successive bits to determine the phase of the input signal.

20. The method of claim 18, wherein step (a2-1) further comprises utilizing a look-up table and bits of the first logic value in the combination result to determine the phase of the input signal.

21. The method of claim 13, wherein step (b) further comprises: (b1) selecting a most frequently occurring phase among the phases of the clock signals to determine the phase of the input signal.

22. The method of claim 21, wherein each of the phase detection results has a plurality of bits each representing one of the clock signals; step (b1) further comprises:
if a phase of a specific clock signal is detected to be a candidate phase of the input signal, setting a first logic value to a specific bit of a phase detection result corresponding to the specific clock signal and a second logic value is set to the remaining bits;
counting occurrence of the first logic value in a specific bit of each phase detection result to generate a plurality of counter values; and
determining the most frequently occurring phase according to the counter values.

23. The method of claim 13, further comprising:
(c) determining a recovery clock signal according to the phase of the input signal determined and the clock signals, and producing a recovery data signal by sampling the input signal according to the recovery clock signal.

24. An method for producing a recovery data signal from an input signal, comprising:
detecting a candidate phase of the input signal referring to a plurality of clock signals having different phases and generating a plurality of phase detection results, wherein each of the phase detection results represents the candidate phase of the input signal and corresponds to one of the clock signals;
determining the phase of the input signal according to the phase detection results; and
determining a recovery clock signal according to the phase of the input signal and the clock signals, and producing a recovery data signal by sampling the input signal according to the recovery clock signal.
